(19) United States
(12) Patent Application Publication
(10) Pub. No.: US 2010/0259916 A1
(43) Pub. Date: Oct. 14, 2010

(54) LIGHT-EMITTING DEVICE AND METHOD FOR FABRICATING THE SAME

(75) Inventor: Jui-Hung Sun, Taipei (TW)

Correspondence Address: LAW OFFICES OF MIKIO ISHIMARU, 333 W. EL CAMINO REAL, SUITE 330, SUNNYVALE, CA, 94087, US

(73) Assignee: AUROTEK CORPORATION, LTD., Taipei City (TW)

(21) Appl. No.: 12/552,793

(22) Filed: Sep. 2, 2009

(30) Foreign Application Priority Data
Apr. 13, 2009 (TW) 098112144

(51) Int. Cl. F21V 9/16; F21V 7/00; H01L 33/00

(52) U.S. Cl. 362/84; 362/310; 438/27; 362/327; 257/E33.056

(57) ABSTRACT

A light-emitting device and a method for fabricating the same are provided. The light-emitting device includes: a substrate; a light-emitting component disposed on the substrate; a lens covering the substrate to hermetically seal the light-emitting component; and a reflective layer formed and a light emission surface defined on the surface of the lens such that light beams generated by the light-emitting component are reflected off the reflective layer, refracted by the light emission surface, and then emitted outward in a specific direction, thereby forming specific light distribution patterns on an illuminated surface outside the light-emitting device.

### BACKGROUND OF THE INVENTION

1. Field of the Invention

This invention generally relates to light-emitting devices and methods for fabricating the same, and more particularly, to a light-emitting device that adopts an LED (Light-Emitting Diode) chip to generate a light beam having directivity and method for fabricating the same.

2. Description of Related Art

In general, lighting is provided by artificial light sources or natural light sources. Compared with natural light sources, artificial light sources which are more diverse in their purposes are used in road illumination, billboard illumination, building illumination, residential illumination, stage illumination, medical illumination, internal and external illumination for vehicles, plant cultivation illumination and so on.

Since traditional illumination devices have the disadvantages, such as high energy consumption, low energy conversion efficiency, and short service life, more and more products are adopting LED technology for illumination purposes. LEDs provide the benefits of small size, low power consumption, long service life, quick responses, low voltage and better directivity. However, due to low intensity of LED lighting, chip package techniques have to be used to establish electrical connection and enhance light emitting efficiency and heat dissipating efficiency.

Referring to FIG. 1, which is a schematic view of a conventional LED package structure, a package structure 10 comprises: a reflective concave cup 11 with an inner wall coated with a reflective metal layer 12; a light-emitting component 13 disposed inside the reflective concave cup 11; and an epoxy resin layer 14 encapsulating the light-emitting component 13.

Light beams 130 generated by the light-emitting component 13 either reach the epoxy resin layer 14 after being reflected off the reflective metal layer 12 or fall on the epoxy resin layer 14 directly, and are refracted and emitted. The design of the packaged lens, however, scatters light and makes it impossible to concentrate light beams so as to enhance brightness without being provided with an additional external secondary optical mechanism.

Referring to FIG. 2, which is a schematic view of another conventional LED package structure, the package structure 20 comprises: a transparent substrate 21; a light-emitting component 22 disposed on a surface of the transparent substrate 21; a lens layer 23 covering the transparent substrate 21; and a reflective layer 24 formed on the lens layer 23 by means of sputtering, wherein the lens layer 23 is used for concentrating light beams. When light beams 220 generated by the light-emitting component 22 reach the lens layer 23, the light beams 220 are reflected off the reflective layer 24 to travel towards the transparent substrate 21 and transmitted through the transparent substrate 21 to the outside.

However, the conventional package structure is unfavorable to the performance of a light-emitting component in terms of efficiency of light emission. Although the conventional package structure changes a path of light emitted and uses a transparent substrate, the transparent substrate is inefficient in heat dissipation. Heat generated by the light-emitting component is not efficiently dissipated by accumulates at the junction of the light-emitting component and the substrate, resulting in high temperature of the light-emitting component and low efficiency of light emission. In short, the conventional package structure is unfavorable to enhancement of brightness.

Hence, it is a highly desirable goal of the industry to provide a technique that can effectively solve the drawbacks of the conventional LED package structures, namely inefficient in concentrating light beams, inefficient in enhancing brightness, inefficient in dissipating heat, and inefficient in providing light beams with directivity.

### SUMMARY OF THE INVENTION

In view of the above drawbacks of the prior art, the present invention provides a light-emitting device, comprising: a substrate; a light-emitting component disposed on the substrate; a lens for covering the substrate to hermetically seal the light-emitting component, wherein the lens has a light emission surface and a reflective layer. The reflective layer is formed on a portion of the surface of the lens. The reflective layer formed on a portion of the surface of the lens reflects and concentrates light beams generated by the light-emitting component so as for the light beams to be emitted from the light emission surface.

A reflective wall is formed on the surface of the substrate to reflect light beams falling thereon so as to increase utilization of light beams. The surface of the lens packaged to cover the substrate is planar, curved or conically curved, irregularly or regularly, smooth or coarse. As mentioned earlier, the reflective layer is formed on a portion of the surface of the lens, and the surface of lens has the remaining portion not covered by the reflective layer such that the remaining portion of the surface of the lens is defined as the light emission surface. The light emission surface is of any profile. Hence, Upon reflection, light beams generated by the light-emitting component reaches the light emission surface, is refracted by the light emission surface, and then is emitted from the light emission surface. The reflective layer concentrates light and defines the effect of the light emitted such that the light beams emitted are diverted and thereby travel in a specific direction, allowing the light beams emitted to fall on an illuminated surface outside the light-emitting device so as to form specific light distribution patterns on the illuminated surface.

The present invention also provides a method for fabricating the light-emitting device, comprising the steps of: providing a light-emitting component and a substrate having a reflective wall, and disposing the light-emitting component on the substrate; providing a lens and packaging the lens on the substrate; and forming a reflective layer on a portion of the surface of the lens by coating.

The substrate is dented to provide a receiving space. The reflective wall defines the receiving space. The light-emitting component is disposed inside the receiving space. The light-emitting component is an LED chip, light beams generated by two sides of which can be completely concentrated and reflected by the reflective wall. The reflective layer is coated on a portion of the surface of the lens, thereby enabling the light beams reflected by the reflective layer to radiate to the outside in a specific direction.

The reflective layer is made of a metal or a non-metal. The metal is gold, silver, aluminum, platinum, or palladium.

Compared with the prior art, the light-emitting device of the present invention and method for fabricating the same essentially comprises a lens partially coated with a reflective layer so as to enable light beams generated by a light-emitting component to radiate to the outside in a specific direction through reflection of the reflective layer, so as to improve directivity of light beams, increase light concentration, form specific light distribution patterns on an illuminated surface outside the light-emitting device, dispense with secondary optical mechanism, and overcome the above drawbacks of the prior art, that is, scattering light cannot be concentrated and thus lacks directivity.

### BRIEF DESCRIPTION OF DRAWINGS

The present invention can be more fully understood by reading the following detailed description of the preferred embodiments and by making reference to the accompanying drawings, wherein:

FIG. 1 (PRIOR ART) is a schematic view of a conventional LED package structure;

FIG. 2 (PRIOR ART) is a schematic view of another conventional LED package structure;

FIG. 3 is a schematic view of a light-emitting device according to an embodiment of the present invention;

FIG. 4 is a perspective diagram of the light-emitting device according to an embodiment of the present invention;

FIG. 5 is a side cross-sectional view of a light-emitting device according to another embodiment of the present invention;

FIG. 6 is a side cross-sectional view of a light-emitting device according to the embodiment shown in FIG. 5;

FIG. 7 is a schematic view according to yet another embodiment of the present invention;

FIG. 8 is a schematic view according to the embodiment illustrated in FIG. 7;

FIG. 9 is a diagram of light distribution patterns according to the embodiment illustrated in FIGS. 7 and 8;

FIG. 10 is a schematic view of a light-emitting device according to a further embodiment of the present invention;

FIG. 11 is a schematic view of a light-emitting device according to the embodiment illustrated in FIG. 10;

FIG. 12 is a schematic view of a light-emitting device according to the embodiment illustrated in FIGS. 10 and 11;

FIG. 13 is a flowchart of a method for fabricating a light-emitting device according to the present invention;

FIG. 14 is a flowchart of a method for fabricating a light-emitting device according to the present invention, wherein the reflective layer is formed by vacuum coating; and

FIG. 15 is a flowchart of a method for fabricating a light-emitting device according to the present invention, wherein the reflective layer is formed by electroplating.

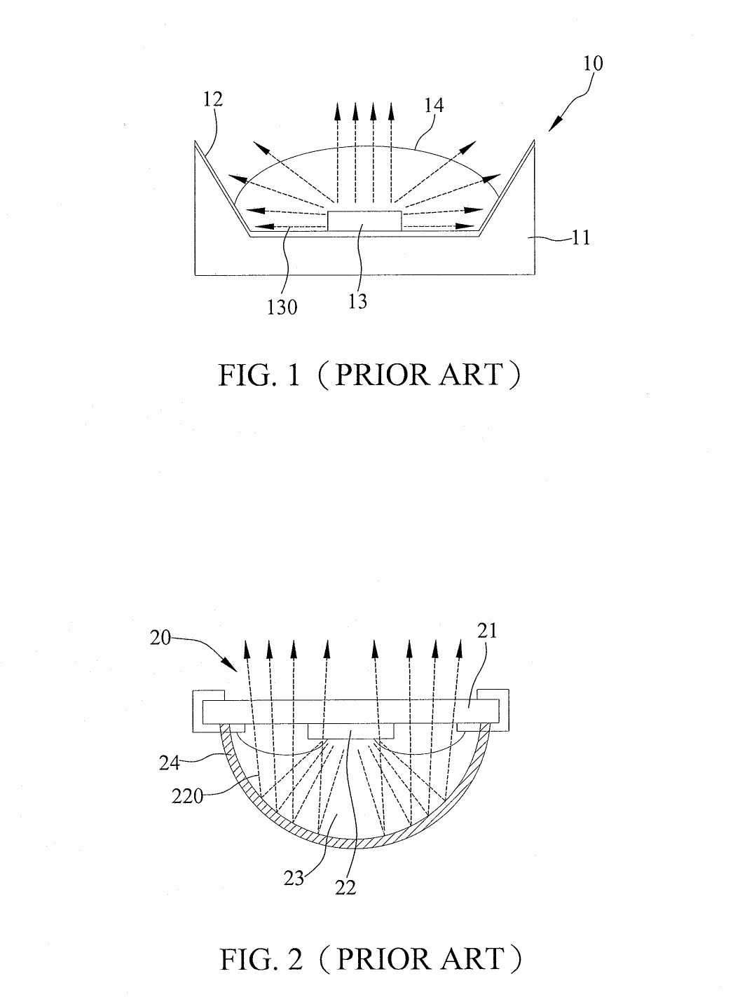

### DETAILED DESCRIPTION OF PREFERRED EMBODIMENTS

The following illustrative embodiments are provided to illustrate the disclosure of the present invention. Advantages and effects of the present invention can be readily understood by those skilled in the art after reading the disclosure of this specification. The present invention can also be performed or applied by other embodiments. The details of the specification may be changed on the basis of different points and applications, and numerous modifications and variations can be devised without departing from the spirit of the present invention.

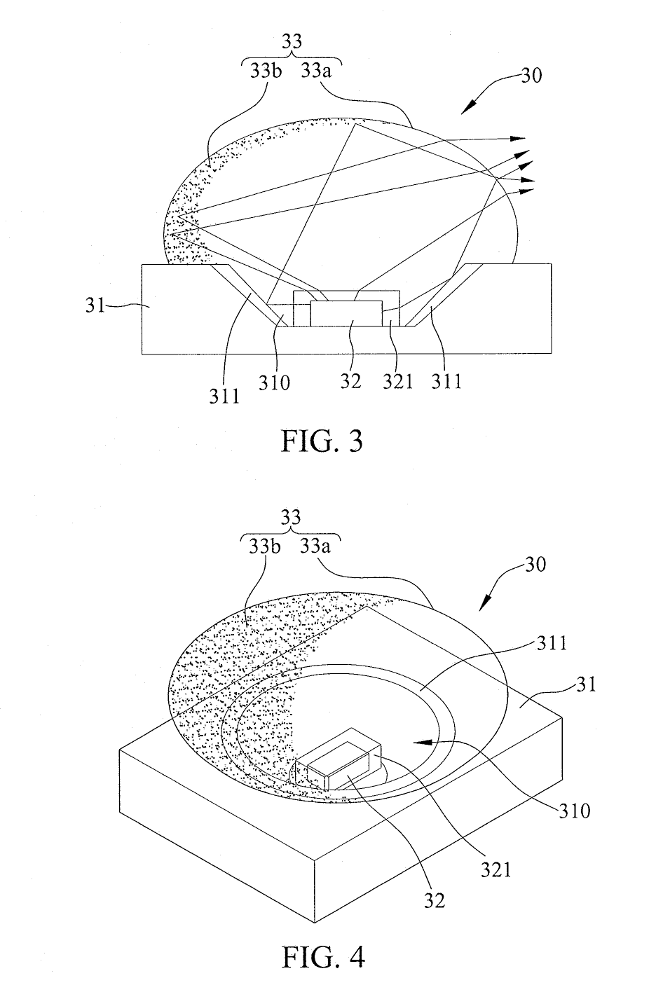

Referring to FIGS. 3 and 4, which are a schematic view and a perspective diagram of a light-emitting device according to an embodiment of the present invention, respectively, a light-emitting device 30 of the present invention comprises: a substrate 31, a light-emitting component 32 disposed on the substrate 31, a lens 33 covering the light-emitting component 32 disposed on the substrate 31, and a light emission surface 33a defined and a reflective layer 33b formed on the surface of the lens 33.

In the present embodiment, the substrate 31 is made of a non-transparent material. The substrate 31 is dented to provide a receiving space 310 of cup shape with the opening being wider than the bottom, and a reflective wall 311 is formed on an inner wall of the substrate 31, wherein the substrate 31 and the receiving space 310 meet at the inner wall.

The light-emitting component 32 is a light-emitting diode (LED) chip disposed inside the receiving space 310 and surrounded by the reflective wall 311 such that light beams generated sideward by the light-emitting component 32 are reflected off the reflective wall 311 of a specific shape and then radiated in a specific direction. In addition, a fluorescent powder layer 321 is coated on the outer surface of the light-emitting component 32 so as to allow light radiated by the chip and characterized by a wavelength to excite the fluorescent powder to thereby be converted into light of anther wavelength. Hence, light beams are sufficiently mixed within the lens before being emitted. For example, blue light emitted by the light-emitting component 32 excites the fluorescent powder to generate yellow light, and then blue light and yellow light mix with each other to produce white light. Also, the fluorescent powder layer 321 is capable of protecting the light-emitting component 32 from external pollution, oxidation, erosion, etc.

The lens 33 is a packaged lens with an arc-shaped surface. The lens 33 is packaged to cover the substrate 31 for protecting the light-emitting component 32 from external pollution, oxidation, and erosion and enhancing the light emitting efficiency.

The reflective layer 33b is formed on a portion of the surface or a specific area of the lens 33 by means of vacuum coating or electroplating such that light beams generated by the light-emitting component 32 are reflected off the reflective layer 33b, penetrate the light emission surface 33a and be emitted therefrom in a pre-determined direction, as shown in FIG 3, thereby concentrating light beams and improving directivity of light beams so as to enhance the light emitting efficiency and light brightness.

In the present embodiment, the reflective layer 33b is formed on one side of the lens 33, therefore, after being reflected off the reflective layer 33b, all light beams generated by the light-emitting component 32 are directed towards the other side (i.e., the light emission surface 33a) of the lens 33 without the reflective layer 33b formed thereon and then are emitted from the light emission surface 33a. Accordingly, when the reflective layer 33b is formed on different positions of the lens 33, light beams are radiated in specific directions, thereby improving emitting directivity of the light beams, increasing light concentration and reducing stray light. In other embodiments, the reflective layer 33b can be formed in another areas to enable light beams generated by the light-emitting component 32 to be emitted in other directions.

It should be noted that the surface of the lens 33 is not limited to the arc-shape. Instead, the surface of the lens 33 can be any curved surface, such as a rounded curved surface, irregularly curved surface, or in other shapes based on the demands of the intended application, thus generating light beams as needed.

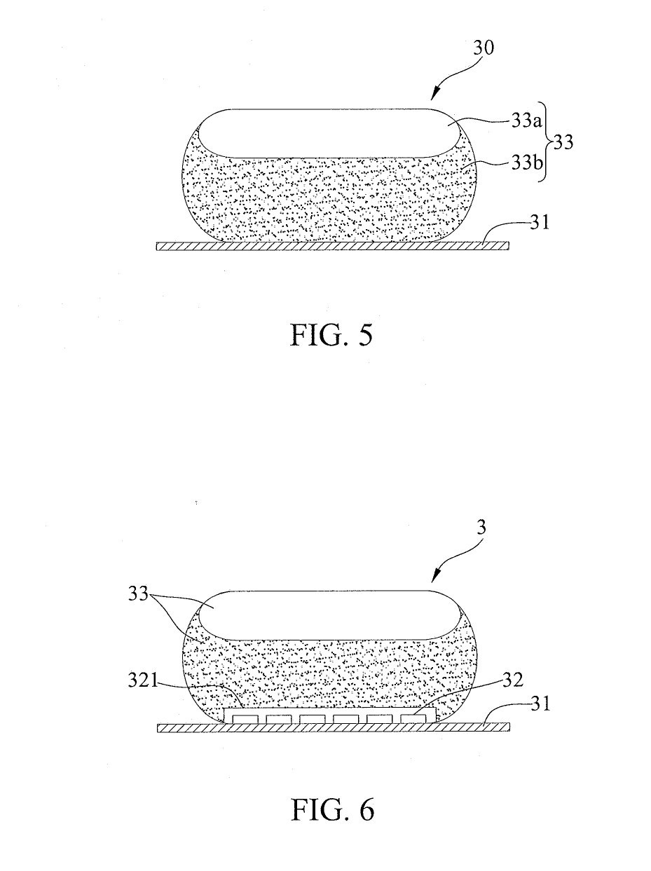

Referring to FIGS. 5 and 6, which are side cross-sectional views of a light-emitting device according to another embodiment of the present invention, respectively, a light-emitting device 30 of the present invention comprises: a substrate 31, a light-emitting component 32 disposed on the substrate 31, a lens 33 covering the light-emitting component 32 disposed on the substrate 31, and a light emission surface 33a defined and a reflective layer 33b formed on the surface of the lens 33.

In the present embodiment, the substrate 31 is made of a non-transparent material. The substrate 31 is dented to provide a receiving space 310 of cup shape with the opening being wider than the bottom, and a reflective wall 311 is formed on an inner wall of the substrate 31, wherein the substrate 31 and the receiving space 310 meet at the inner wall.

The light-emitting component 32 is a light-emitting diode (LED) chip disposed inside the receiving space 310 and surrounded by the reflective wall 311 such that light beams generated sideward by the light-emitting component 32 are reflected off the reflective wall 311 of a specific shape and then radiated in a specific direction. In addition, a fluorescent powder layer 321 is coated on the outer surface of the light-emitting component 32 so as to allow light radiated by the chip and characterized by a wavelength to excite the fluorescent powder to thereby be converted into light of anther wavelength. Hence, light beams are sufficiently mixed within the lens before being emitted. For example, blue light emitted by the light-emitting component 32 excites the fluorescent powder to generate yellow light, and then blue light and yellow light mix with each other to produce white light. Also, the fluorescent powder layer 321 is capable of protecting the light-emitting component 32 from external pollution, oxidation, erosion, etc.

The lens 33 is a packaged lens with a planar, arc-shaped, regular, irregular, or conical surface, whether coarse or smooth. The lens 33 is packaged to cover the substrate 31 for protecting the light-emitting component 32 from external pollution, oxidation, and erosion and enhancing the light emitting efficiency. Normally, the lens 33 is a hollow cover-like structure and thereby has a receiving space whereby a light-emitting component is hermetically sealed.

The reflective layer 33b is formed in a specific area of the surface of the lens 33 by means of vacuum coating or electroplating. Referring to FIG. 5, specifically speaking, in an embodiment, the reflective layer 33b is formed on a side-wall of the lens 33 such that light beams generated by the light-emitting component 32 are reflected off the reflective layer 33b, penetrate the light emission surface 33a and be emitted therefrom in a pre-determined direction, thereby increasing utilization of light emitted and brightening an illuminated surface outside the light-emitting device.

In the present embodiment, the reflective layer 33b is formed in a major one-sided portion of the surface of the lens 33 so as for light beams generated by the light-emitting component 32 to be reflected off the reflective layer 33b before falling on the light emission surface 33a. The light emission surface 33a is defined as an area not formed with the reflective layer 33b. The reflective layer 33b formed on the lens 33 takes on a curved profile for concentrating light beams. As mentioned above, light beams generated by the light-emitting component 32 are reflected off the reflective layer 33b, fall on the light emission surface 33a, and are refracted before being emitted. Given the selection of the position of the reflective layer 33b and the design of the refractive surface of the light emission surface 33a, light beams are emitted in a specific direction, and thus the light beams emitted feature directivity, concentration, and less stray light. In another embodiment, the reflective layer 33b is formed in another specific area to allow light beams generated by the light-emitting component 32 to be emitted in another specific direction.

It should be noted that the surface of the lens 33 is not limited to the arc-shape. Instead, the surface of the lens 33 can be any curved surface, such as a rounded curved surface, irregularly curved surface, or in other shapes based on the demands of the intended application, thus generating light beams as needed.

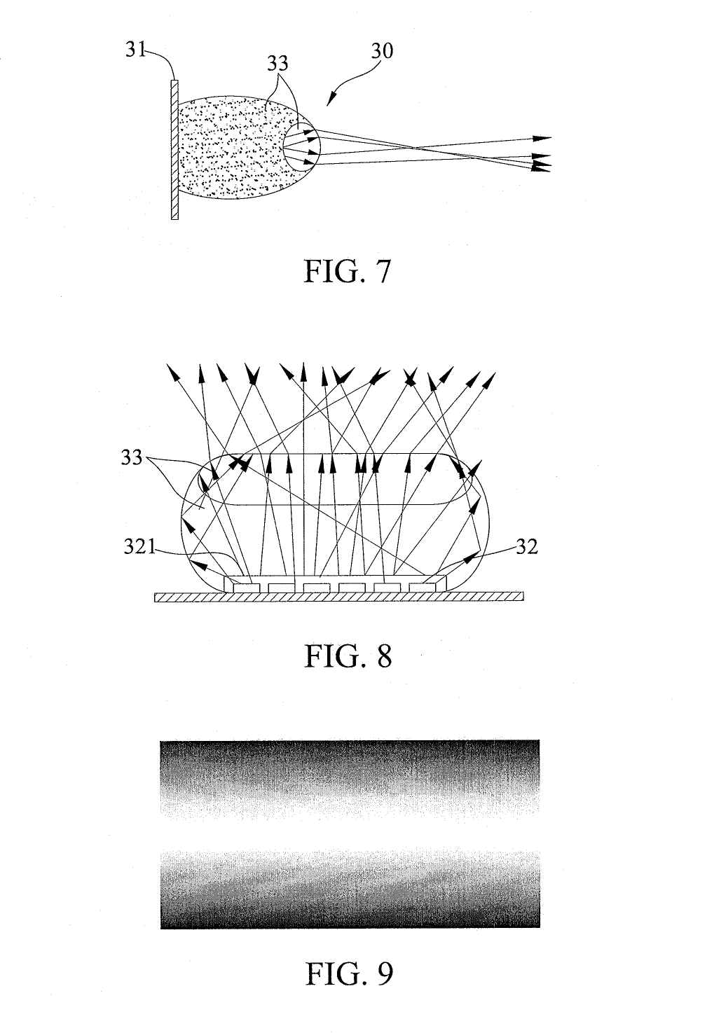

Referring to FIGS. 7, 8 and 9, schematic views and a diagram of light distribution patterns according to yet another embodiment of the present invention are shown. As shown in the drawings, light beams generated by the light-emitting component 32 are reflected off the reflective layer 33b and emitted from the light emission surface 33a to the outside so as to provide uniform concentrated light distribution. Hence, the light beams emitted feature enhanced directivity, and specific light distribution patterns are formed on an illuminated surface (not shown) outside the light-emitting device as shown in FIG. 9, so as to provide proper luminosity within an illuminated range.

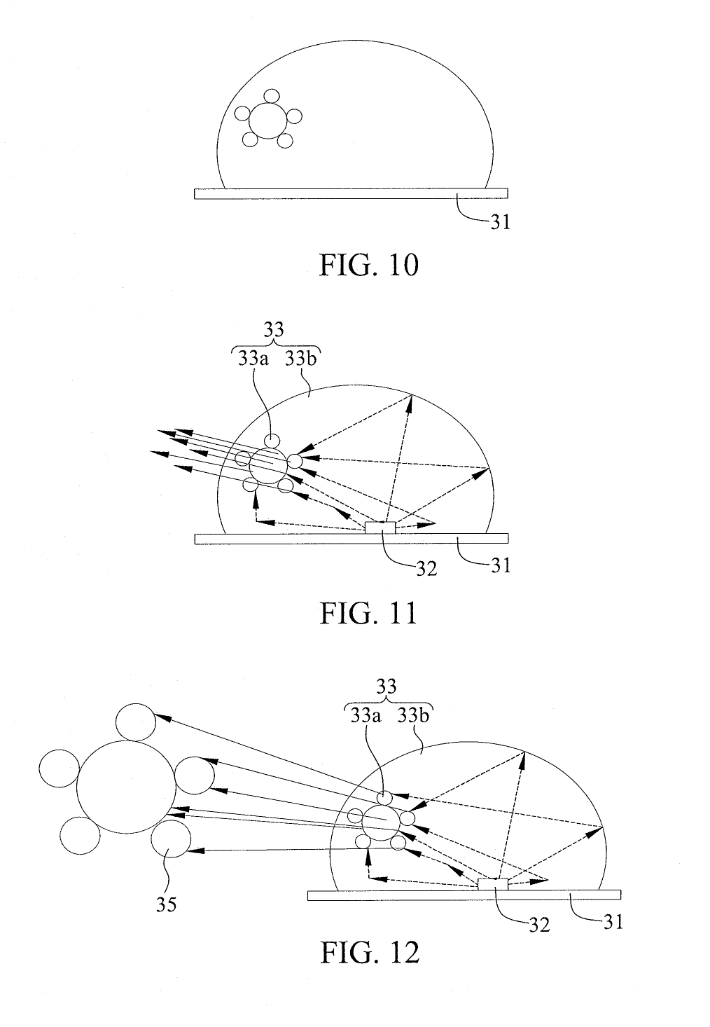

Referring to FIGS. 10, 11, and 12, which are schematic views of a light-emitting device according to a further embodiment of the present invention, light beams generated by the light-emitting component 32 are reflected off the reflective layer 33b and emitted from the light emission surface 33a to the outside so as to provide uniform concentrated light distribution. With the light emission surface 33a being of any desirable shape, the light beams emitted feature enhances directivity, and specific light distribution patterns 35 are formed on an illuminated surface outside the light-emitting device, so as to provide proper luminosity within an illuminated range and the light distribution patterns required.

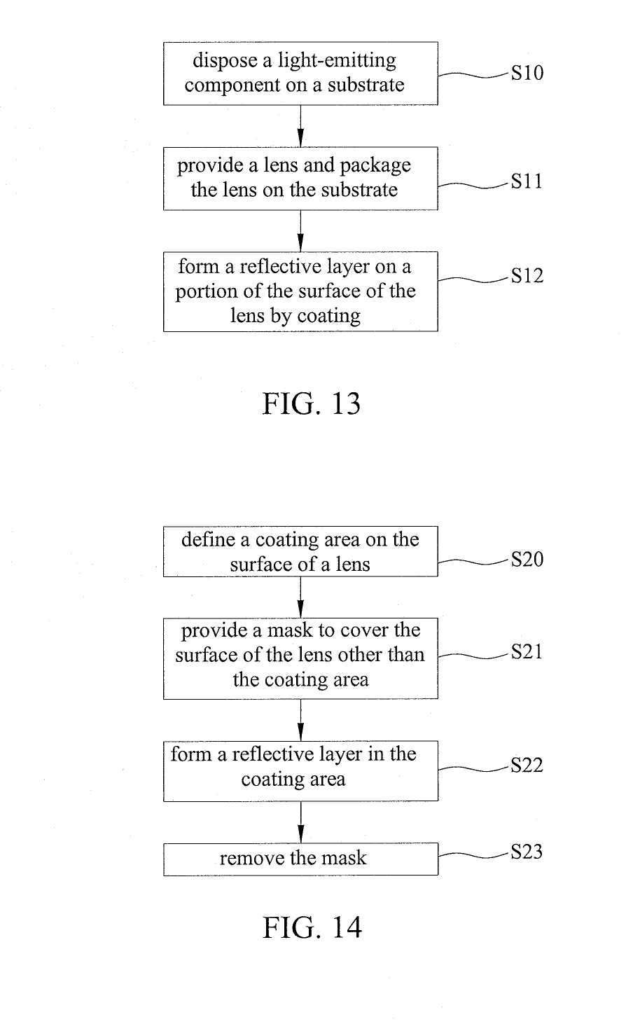

Referring to FIG. 13, a flowchart of a method for fabricating a light-emitting device according to the present invention is shown. Referring to FIG. 13 in conjunction with FIG. 4 or FIG. 6, the method for fabricating a light-emitting device according to the present invention comprises the following steps.

In step S10, a light-emitting component is disposed on a substrate. Optionally, the substrate has a reflective wall. Then, the process goes to step S11.

In step S11, a lens is provided and the lens is packaged on the substrate. Then, the process goes to step S12.

In step S12, a reflective layer is formed on a portion of the surface of the lens by coating, such as vacuum coating, electroplating or the like.

FIG. 14 is a flowchart of a method for fabricating a light-emitting device according to the present invention, wherein the reflectively layer is formed by vacuum coating. As shown in the drawing, the method comprises the following steps.

In step S20, a coating area is defined on the surface of a lens. Then, the process goes to step S21.

In step S21, a mask is provided for covering the surface of the lens other than the coating area. Then, the process goes to step S22.

In step S22, a reflective layer is formed on a portion of the surface of the lens (that is, in the coating area) by vacuum coating. Then, the process goes to step S23.

In step S23, the mask is removed.

Thus, a reflective layer is formed in a specific area of the surface of the lens.

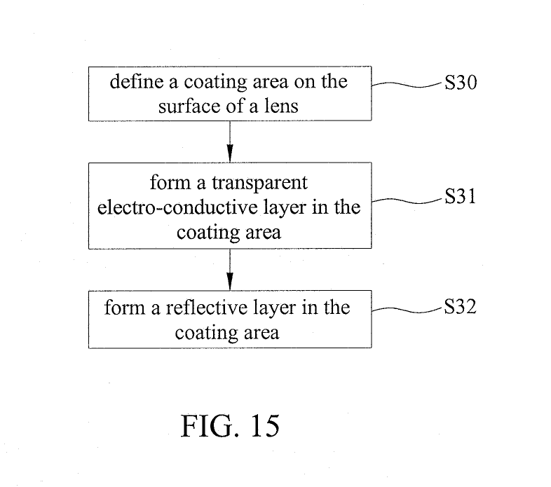

FIG. 15 is a flowchart of a method for fabricating a light-emitting device according to the present invention, wherein the reflective layer is formed by electroplating. As shown in the drawing, the method comprises the following steps.

In step S30, a coating area is defined on the surface of a lens. Then, the process goes to step S31.

In step S31, a transparent electro-conductive layer is formed in the coating area. Then, the process goes to step S32.

In step S32, a reflective layer is formed in the coating area by electroplating.

Thus, a reflective layer is formed in a specific area of the lens surface.

It should be noted that, in addition to vacuum coating and electroplating, other ways of coating may be adopted to form the reflective layer. Since the ways of coating are well known in the art and are not attributed to technical features of the present invention, detailed description thereof is omitted herein.

In the present embodiment, preferably, prior to the step 11 of providing a lens, a fluorescent powder layer 321 are formed to cover the light-emitting component 32, or the light-emitting component 32 provided in step 10 is initially covered with the fluorescent powder layer 321, such that blue light generated by the light-emitting component 32 excites the florescent powder to generate yellow light, thereby forming white light by combining the blue light and yellow light. The florescent powder layer 321 also protects light-emitting component 32 from external pollution, oxidation, erosion etc.

In the present embodiment, preferably, the substrate 31 is dented to provide a receiving space 310 of cup shape with the opening being wider than the bottom. In addition, the reflective wall 311 is disposed on the wall of the receiving space 310, and the light-emitting component 32 is a light-emitting diode (LED) chip disposed inside the receiving space 310 and surrounded by the reflective wall 311. Accordingly, light beams generated by sides of the light-emitting component 32 can be gathered by the reflective wall 311 and radiated in a desired direction.

In the present embodiment, the light-emitting component 32 is a light-emitting diode (LED) chip disposed on the substrate 31 such that light beams generated by the light-emitting component 32 are reflected off the reflective layer 33b, penetrate the light emission surface 33a and be emitted therefrom in a pre-determined direction. Furthermore, the lens 33 is a packaged lens with an arc-shaped curved surface, and packaged on the substrate 31. The reflective layer 33b is formed in a specific area of the lens 33 such that light beams generated by the light-emitting component 32 are reflected off the reflective layer 33b, penetrate the light emission surface 33a and be emitted therefrom in a pre-determined direction, so as to form specific light distribution patterns on an illuminated surface (not shown) outside the light-emitting device, thereby providing light beams characterized by enhanced directivity and specific light distribution patterns, increasing light beam concentration, lessening stray light, and enhancing light emitting efficiency.

In summary, the light-emitting device of the present invention and method for fabricating the same are characterized by providing light beams having directivity, which is accomplished mainly by forming a reflective layer on a portion of surface or a specific area of the lens such that when light beams generated by the light-emitting component reach the reflective layer, they can be reflected so as to radiate in a specific direction, thus increasing light concentration and enhancing light emitting efficiency. Accordingly, by forming the reflective layer in different portions and areas of the surface of the lens, light beams of different directivity are generated as needed. Furthermore, the present invention has simple structure with low fabrication costs, thereby reducing the overall fabrication costs. In view of the above, the light-emitting device of the present invention and method for fabricating the same have effectively and practically overcome the aforesaid drawbacks of the prior art, namely, being incapable of forming light beams having specific directivity and concentrating light, and low efficiency.

The foregoing descriptions of the detailed embodiments are only illustrated to disclose the features and functions of the present invention and are not restrictive of the scope of the present invention. It should be understood by those in the art that various modifications and variations made according to the spirit and principles in the disclosure of the present invention should fall within the scope of the appended claims.

What is claimed is:

1. A light-emitting device, comprising:
a substrate;
a light-emitting component disposed on the substrate; and
a lens provided on the substrate for covering the light-emitting component, the lens having a reflective layer and a light emission surface, and the reflective layer being formed on a portion of the surface of the lens so as for light beams generated by the light-emitting component to be emitted from the light emission surface.

2. The device of claim 1, wherein the reflective layer is formed on a portion of the surface of the lens and the light emission surface is defined on another portion of the surface of the lens and with a specific shape so as for the light beams to be emitted in a specific direction and form specific light distribution patterns.

3. The device of claim 1, wherein the substrate has a reflective wall.

4. The device of claim 3, wherein the reflective layer is formed on a portion of the surface of the lens and the light emission surface is defined on another portion of the surface of the lens and with a specific shape so as for the light beams to be emitted in a specific direction and form specific light distribution patterns.

5. The device of claim 4, wherein the substrate is dented to provide a receiving space, allowing the reflective wall to define the receiving space.

6. The device of claim 5, wherein the light-emitting component is disposed inside the receiving space.

7. The device of claim 1, wherein the light-emitting component is a light-emitting diode (LED) chip.

8. The device of claim 1, wherein the surface of the light-emitting component is covered with a fluorescent powder layer.

9. The device of claim 1, wherein the lens is a packaged lens.

10. The device of claim 1, wherein a surface of the lens is of a shape selected from the group consisting of an arc-shaped surface, a rounded curved surface, and an irregularly curved surface.

11. The device of claim 1, wherein the reflective layer is made of a metal.

12. The device of claim 11, wherein the metal is one selected from the group consisting of gold, silver, aluminum, platinum, and palladium.

13. The device of claim 1, wherein the reflective layer is made of a non-metal.

14. The device of claim 13, wherein the light emission surface of the lens allows the light beams to be refracted by means of material-related or structure-related properties of the lens and emitted.

15. A method for fabricating a light-emitting device, comprising the steps of:
providing a substrate;
disposing a light-emitting component on the substrate;
covering the light-emitting component on the substrate with a lens; and
forming a reflective layer on a portion of a surface of the lens by coating.

16. The method of claim 15, wherein the substrate has a reflective wall.

17. The method of claim 15, covering, after the step of disposing the light-emitting component on the substrate, the light-emitting component with a fluorescent powder layer.

18. The method of claim 17, wherein the coating is vacuum coating.

19. The method of claim 18, wherein the coating comprises the steps of:
defining a coating area on the surface of the lens;
covering a portion of the surface of the lens other than the coating area with a mask;
forming a reflective layer on the coating area of the lens; and
removing the mask.

20. The method of claim 15, wherein the coating is electroplating.

21. The method of claim 20, wherein the coating comprises the steps of:
defining a coating area on the surface of the lens;
forming a transparent electro-conductive layer in the coating area of the lens; and
forming a reflective layer on the transparent electro-conductive layer in the coating area.

22. The method of claim 15, wherein the substrate is dented to provide a receiving space, and the reflective wall defines the receiving space.

23. The method of claim 22, wherein the light-emitting component is disposed inside the receiving space.

24. The method of claim 23, wherein the light-emitting component is a light-emitting diode (LED) chip.

25. The method of claim 24, wherein the metal is one selected from the group consisting of gold, silver, aluminum, platinum, and palladium.

26. The method of claim 15, wherein the surface of the lens is of a shape selected from the group consisting of an arc-shaped surface, a rounded curved surface, and an irregularly curved surface.

27. The method of claim 15, wherein the reflective layer is made of a metal.

28. The method of claim 15, wherein the reflective layer is made of a non-metal.
